(19) United States
(12) Patent Application Publication
(10) Pub. No.: US 2023/0402263 A1
(43) Pub. Date: Dec. 14, 2023

(54) PLASMA TREATMENT DEVICE AND ELECTRODE MECHANISM

(71) Applicant: Tokyo Electron Limited, Tokyo (JP)

(72) Inventor: Naoki MATSUMOTO, Miyagi (JP)

(73) Assignee: Tokyo Electron Limited, Tokyo (JP)

(21) Appl. No.: 18/239,006

(22) Filed: Aug. 28, 2023

Related U.S. Application Data
(63) Continuation of application No. PCT/JP2022/017038, filed on Apr. 4, 2022.

(30) Foreign Application Priority Data
Apr. 6, 2021 (JP) 2021-064704

(51) Int. Cl. H01J 37/32

(52) U.S. Cl. CPC H01J 37/32651; H01J 37/32642; H01J 37/32559; H01J 37/32568; H01J 37/32724

(57) ABSTRACT

A plasma processing apparatus includes: a processing chamber, and an electrode mechanism used for plasma processing. The electrode mechanism includes: an electrode portion configured to be applied with radio-frequency power, a dielectric portion disposed to laminate with the electrode portion, an electric circuit at least partially disposed in the dielectric portion, and a shield member disposed in the dielectric portion to overlap at least a part of the electric circuit in at least one of a plan view or a side view.

### CROSS-REFERENCE TO RELATED APPLICATIONS

This application is a bypass continuation application of International Application No. PCT/JP2022/017038 having an international filing date of Apr. 4, 2022, and designating the United States, the International Application being based upon and claiming the benefit of priority from Japanese Patent Application No. 2021-064704, filed on Apr. 6, 2021, the entire contents of which are incorporated herein by reference and priority is claimed to each.

### TECHNICAL FIELD

The present disclosure relates to a plasma processing apparatus and an electrode mechanism.

### BACKGROUND

JP-A-2015-173027 discloses a plasma processing apparatus that includes a heater power supply electrically connected to, via a heater power feed line, a heating element provided in a stage supporting an object. A filter provided on the heater power feed line attenuates or prevents radio-frequency noise entering the heater power feed line from the heating element toward the heater power supply.

### SUMMARY

The technique according to the disclosure appropriately prevents radio-frequency power as a noise component from entering an electric circuit disposed in a plasma processing apparatus.

According to an aspect of the disclosure, a plasma processing apparatus includes: a processing chamber, and an electrode mechanism used for plasma processing. The electrode mechanism includes an electrode portion configured to be applied with radio-frequency power, a dielectric portion disposed to laminate with the electrode portion, an electric circuit at least partially disposed in the dielectric portion, and a shield member disposed in the dielectric portion to overlap at least a part of the electric circuit in at least one of a plan view or a side view.

### BRIEF DESCRIPTION OF THE DRAWINGS

FIG. 1 is a vertical sectional view illustrating a configuration example of a plasma processing system according to the present embodiment.

FIG. 2 is a vertical sectional view illustrating a configuration example of a substrate support according to the present embodiment.

FIG. 3 is a vertical sectional view illustrating a configuration example of a substrate support according to another embodiment.

FIG. 4 is a vertical sectional view illustrating a configuration example of a substrate support according to another embodiment.

FIG. 5 is a view illustrating a flow of radio-frequency power in a substrate support in the prior art.

FIG. 6 is a view illustrating a flow of radio-frequency power in the substrate support according to the embodiment.

FIG. 7 is a vertical sectional view illustrating a configuration example of a substrate support according to another embodiment.

FIG. 8 is a vertical sectional view illustrating a configuration example of a substrate support according to another embodiment.

FIG. 9 is a vertical sectional view illustrating a configuration example of a substrate support according to another embodiment.

FIG. 10 is a vertical sectional view illustrating a configuration example of a substrate support according to another embodiment.

FIG. 11 is a vertical sectional view illustrating a configuration example of a substrate support according to another embodiment.

FIG. 12 is a vertical sectional view illustrating a configuration example of a substrate support according to another embodiment.

FIG. 13 is a vertical sectional view illustrating a configuration example of a substrate support according to another embodiment.

FIG. 14 is a vertical sectional view illustrating a configuration example of an upper electrode mechanism according to one embodiment.

### DETAILED DESCRIPTION

In a process of manufacturing a semiconductor device, various types of plasma processing such as an etching process, a film formation process, and a diffusion process are performed on a semiconductor substrate (hereinafter, simply referred to as “substrate”) supported by a substrate support, by exciting a processing gas supplied into a chamber to generate plasma. The substrate support that supports the substrate is provided with, for example, an electrostatic chuck for attracting and holding the substrate on a placement surface by a coulomb force or the like, and an electrode portion applied with radio-frequency power during the plasma processing.

In the plasma processing described above, in order to improve the uniformity of process characteristics with respect to the substrate, it is required to appropriately adjust temperature distribution of a substrate to be processed. The temperature distribution of the substrate during the plasma processing is adjusted by, for example, providing multiple heating elements (e.g., heaters) in the electrostatic chuck and controlling the temperature of the placement surface for each of a plurality of temperature control regions defined by the heating elements. The heating elements disposed in the electrostatic chuck are connected to, via corresponding power feeding cables, a heating element power source for supplying power to the heating elements.

In each of the power feeding cables that connect the heating elements and the heating element power source, when a part of the radio-frequency waves that are applied from a radio-frequency (RF) power source to the electrode portion during plasma generation enters as common mode noise (hereinafter, simply referred to as “radio-frequency noise”), an abnormal discharge or a backflow of the radio-frequency power may occur. In particular, when the entered radio-frequency noise reaches the heating element power source, the heating element power source may be damaged or malfunction. Therefore, in the plasma processing apparatus, as disclosed in JP-A-2015-173027, an RF cut filter (filter unit) for attenuating or preventing the radio-frequency noise is disposed on the power feeding cable (line).

Accordingly, in the plasma processing apparatus described in JP-A-2015-173027, the RF cut filter is used to attenuate the radio-frequency noise entering the power feeding cable, but the radio-frequency noise cannot be completely prevented and there was a risk that a portion of the radio-frequency noise may partially reach the heating element power source. If a part of the radio-frequency noise reaches the heating element power source in this way, as described above, the heating element power source may be damaged or malfunction.

The RF cut filter disposed on the power feeding cable acts as a resistor when the radio-frequency noise passes through, which may cause loss of the radio-frequency power and reduce the power efficiency. Further, if there is a deviation in a resistance value of the RF cut filter disposed on the power feeding cable, such variation in the resistance value may appear as a difference in plasma processing apparatus.

The technique according to the disclosure has been made in view of the circumstances described above, and appropriately prevents radio-frequency power as a noise component from entering the electric circuit disposed in a plasma processing apparatus. Hereinafter, a plasma processing system including the plasma processing apparatus according to the present embodiment will be described with reference to the drawings. The same reference numerals will be given to elements having substantially the same functional configurations throughout the specification and the drawings, and redundant description thereof will be omitted.

<Plasma Processing Apparatus>

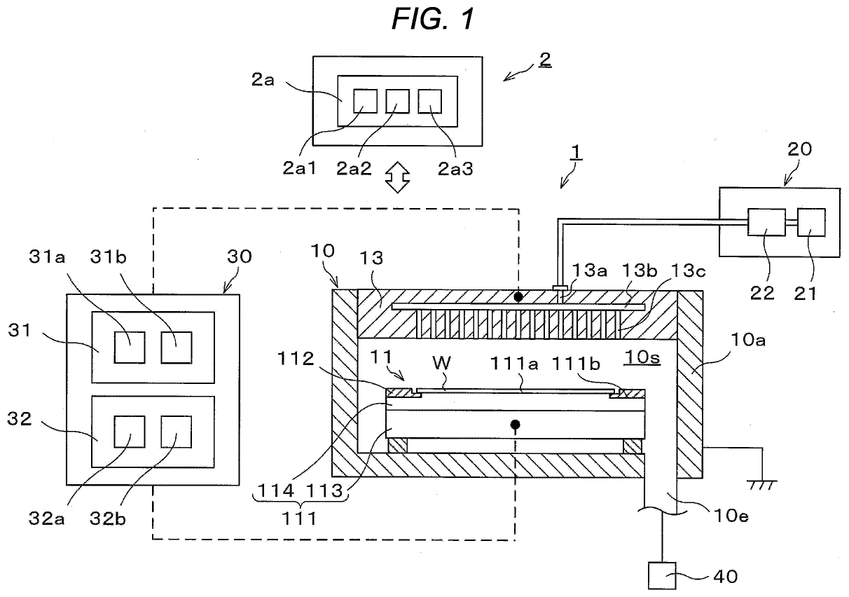

First, a plasma processing system according to the present embodiment will be described. FIG. 1 is a vertical sectional view illustrating a configuration of the plasma processing system according to the present embodiment.

The plasma processing system includes a capacitively-coupled plasma processing apparatus 1 and a controller 2. The plasma processing apparatus 1 includes a plasma processing chamber 10, a gas supply 20, a power source 30, and an exhaust system 40. Further, the plasma processing apparatus 1 includes a substrate support 11 and a gas introduction unit. The substrate support 11 is disposed inside the plasma processing chamber 10. The gas introduction unit is configured to introduce at least one processing gas into the plasma processing chamber 10. The gas introduction unit includes a shower head 13. The shower head 13 is disposed above the substrate support 11. In one embodiment, the shower head 13 constitutes at least a part of a ceiling of the plasma processing chamber 10. A plasma processing space 10s defined by the shower head 13, a sidewall 10a of the plasma processing chamber 10, and the substrate support 11 is formed in the plasma processing chamber 10. The plasma processing chamber 10 has at least one gas supply port for supplying at least one processing gas into the plasma processing space 10s, and at least one gas exhaust port for exhausting the gas from the plasma processing space 10s. The plasma processing chamber 10 is grounded. The shower head 13 and the substrate support 11 are electrically insulated from the plasma processing chamber 10.

The substrate support 11 includes a body member 111 serving as an electrode mechanism and a ring assembly 112. An upper surface of the body member 111 has a central region 111a (a substrate support surface) for supporting a substrate (wafer) W, and an annular region 111b (a ring support surface) for supporting the ring assembly 112. The annular region 111b surrounds the central region 111a in a plan view. The ring assembly 112 includes one or more annular members, and at least one of the one or more annular members is an edge ring.

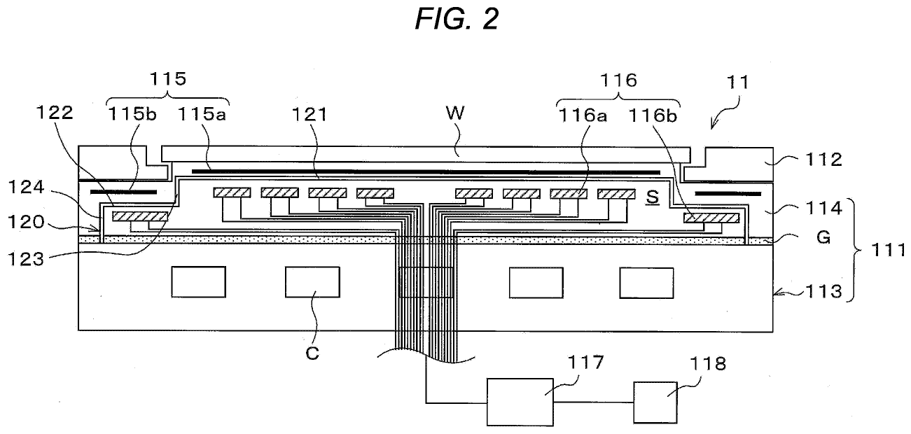

As illustrated in FIG. 2, in one embodiment, the body member 111 includes a base 113 serving as an electrode portion and an electrostatic chuck 114. The base 113 and the electrostatic chuck 114 are laminated and joined to each other via an adhesive member G. In the present embodiment, the electrostatic chuck 114 and the adhesive member G configuring the body member 111 correspond to the “dielectric portion” according to the technique of the present disclosure.

The base 113 is configured by, for example, a conductive member such as an Al alloy. The conductive member of the base 113 functions as a lower electrode. A flow path C is formed in the base 113. A heat transfer medium (fluid for temperature control) from a chiller unit (not illustrated) is circulated and supplied to the flow path C. Then, the heat transfer medium is circulated through the flow path C to adjust the temperature of the ring assembly 112, the electrostatic chuck 114 to be described later, and the substrate W to a desired temperature. As the heat transfer medium, for example, a coolant such as cooling water can be used.

The electrostatic chuck 114 is laminated and joined to an upper surface of the base 113. The upper surface of the electrostatic chuck 114 has the central region 111a and the annular region 111b described above. An adsorption electrode 115, a heater electrode 116, and a shield member 120 are provided in the electrostatic chuck 114. The electrostatic chuck 114 is configured by, for example, interposing the adsorption electrode 115, the heater electrode 116, and the shield member 120 between a pair of dielectric films made of a nonmagnetic dielectric such as ceramic.

The adsorption electrode 115 has a first adsorption electrode 115a for adsorbing and holding the substrate W on the central region 111a, and a second adsorption electrode 115b for adsorbing and holding the ring assembly 112 on the annular region 111b. The adsorption electrode 115 is connected to an adsorption power source (not illustrated). When a voltage is applied from the adsorption power source to the adsorption electrode 115, an electrostatic force such as a coulomb force is generated and the substrate W is adsorbed and held on the electrostatic chuck 114 by the electrostatic force.

As the adsorption power source, the power source 30 to be described later illustrated in FIG. 1 may be used, or an adsorption power source (not illustrated) independent from the power source 30 may be connected.

The heater electrode 116 serving as an electric circuit includes one or more first heater electrodes 116a for heating the substrate W, and one or more second heater electrodes 116b for heating the ring assembly 112. A heating power source 118 is connected to the heater electrode 116 via an RF cut filter 117. The heater electrode 116 generates heat by receiving power from the heating power source 118, and heats at least one of the ring assembly 112, the electrostatic chuck 114, and the substrate W.

During plasma generation in the plasma processing space 10s, when the radio-frequency power applied from an RF power source 31 to be described later to the conductive member of the base 113 enters the heater electrode 116 as a noise component, the RF cut filter 117 prevents the noise component from reaching the heating power source 118.

The heating power source 118 is configured to individually control energization of each of the heater electrodes 116 by, for example, the controller 2 to be described later. In other words, the electrostatic chuck 114 is configured to control the temperature of the central region 111a (the substrate W) and the annular region 111b (the ring assembly 112) for each of temperature control regions defined by each of the heater electrodes 116 or combinations thereof in a plan view. As the heating power source 118, the power source 30 to be described later illustrated in FIG. 1 may be used, or the heating power source 118 independent from the power source 30 may be connected.

The shield member 120 is made of, for example, a conductive metal material that has a sufficiently low resistance value with respect to the radio-frequency power to be applied to the conductive member of the base 113, that is, a conductive metal material (for example, tungsten or titanium) that prevents transmission loss of the radio-frequency power and attenuates or prevents transmission of the radio-frequency power.

The shield member 120 is provided in the electrostatic chuck 114 to surround at least the periphery of the heater electrode 116. Specifically, in one embodiment, the shield member 120 includes a first top plate member 121 having a substantially disk shape disposed to cover the first heater electrodes 116a in a plan view, a second top plate member 122 having a substantially annular shape disposed to cover the second heater electrode 116b in a plan view, a first sidewall member 123 having a substantially cylindrical shape disposed to surround the first heater electrodes 116a in a side view, and a second sidewall member 124 having a substantially cylindrical shape disposed to surround the second heater electrode 116b in a side view.

In other words, in one embodiment, the shield member 120 has, in the electrostatic chuck 114, top plate members provided opposite to the base 113 with respect to the heater electrode 116 in a laminating direction of the base 113 and the electrostatic chuck 114. In addition, the shield member 120 has, in the electrostatic chuck 114, sidewall members provided outside the heater electrodes 116 in a radial direction.

More specifically, the first top plate member 121 is disposed between the first adsorption electrode 115a and the first heater electrode 116a along a surface direction of the electrostatic chuck 114. In addition, the second top plate member 122 is disposed between the second adsorption electrode 115b and the second heater electrode 116b along the surface direction. The first sidewall member 123 is disposed along the laminating direction of the base 113 and the electrostatic chuck 114, that is, a thickness direction of the electrostatic chuck 114, to electrically connect the first top plate member 121 and the second top plate member 122. The second sidewall member 124 is disposed along the laminating direction (the thickness direction) to electrically connect the second top plate member 122 and the base 113. That is, in one embodiment, the shield member 120 is disposed in the electrostatic chuck 114 to be substantially the same potential as that of the base 113.

In other words, in one embodiment, the heater electrode 116 disposed in the electrostatic chuck 114 is disposed to be substantially accommodated in an equipotential space S (see FIG. 2) defined by the base 113 and the shield member 120 that are disposed to be substantially the same potential.

It is desirable that the first top plate member 121 and the second top plate member 122 that are disposed along the surface direction of the electrostatic chuck 114 are disposed at positions closer to the adsorption electrode 115 (more preferably, a surface of the electrostatic chuck 114) than the heater electrode 116 in the thickness direction of the electrostatic chuck 114. In other words, it is desirable to determine positions of the top plate members such that distances between the heater electrode 116 and the top plate members are larger than distances between the adsorption electrode 115 (more preferably, the surface of the electrostatic chuck 114) and the top plate members. By bringing the top plate members of the shield member 120 close to the surface of the electrostatic chuck 114 in this way, the top plate members can function as a bias electrode during the plasma processing, and a power efficiency during the plasma generation can be improved.

Although not illustrated, the substrate support 11 may include a heat transfer gas supply configured to supply a heat transfer gas (a backside gas) between a rear surface of the substrate W and the upper surface of the electrostatic chuck 114.

Referring back to FIG. 1, the shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied from the gas supply 20 to the gas supply port 13a passes through the gas diffusion chamber 13b and is introduced into the plasma processing space 10s from the gas introduction ports 13c. Further, the shower head 13 includes a conductive member. The conductive member of the shower head 13 functions as an upper electrode. In addition to the shower head 13, the gas introduction unit may include one or more side gas injectors (SGI) that are attached to one or more openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include one or more flow rate modulation devices that modulate or pulse flow rates of at least one processing gas.

The power source 30 includes the RF power source 31 coupled to the plasma processing chamber 10 via at least one impedance matching circuit. The RF power source 31 is configured to supply at least one RF signal (RF power), such as a source RF signal and a bias RF signal, to at least one of a conductive member (the lower electrode) of the substrate support 11 and a conductive member (the upper electrode) of the shower head 13. Accordingly, plasma is formed from at least one processing gas supplied into the plasma processing space 10s. Accordingly, the RF power source 31 may function as at least a part of a plasma generator configured to generate plasma from one or more processing gases in the plasma processing chamber 10. In addition, by supplying the bias RF signal to the lower electrode, a bias potential can be generated in the substrate W to draw an ion component in the formed plasma to the substrate W.

In one embodiment, the RF power source 31 includes a first RF generator 31a and a second RF generator 31b. The first RF generator 31a is coupled to at least one of the lower electrode and the upper electrode via at least one impedance matching circuit and configured to generate the source RF signal (source RF power) for plasma generation. In one embodiment, the source RF signal has a frequency in a range of 13 MHz to 150 MHz. In one embodiment, the first RF generator 31a may be configured to generate a plurality of source RF signals having different frequencies. The generated one or more source RF signals are supplied to at least one of the lower electrode and the upper electrode. The second RF generator 31b is coupled to the lower electrode via at least one impedance matching circuit and configured to generate the bias RF signal (bias RF power). In one embodiment, the bias RF signal has a lower frequency than that of the source RF signal. In one embodiment, the bias RF signal has a frequency within a range of 400 kHz to 13.56 MHz. In one embodiment, the second RF generator 31b may be configured to generate a plurality of bias RF signals having different frequencies. The generated one or the plurality of bias RF signals are supplied to the lower electrode. In addition, in various embodiments, at least one of the source RF signal and the bias RF signal may be pulsed.

Further, the power source 30 may include a DC power source 32 coupled to the plasma processing chamber 10. The DC power source 32 includes a first DC generator 32a and a second DC generator 32b. In one embodiment, the first DC generator 32a is connected to the lower electrode and configured to generate a first DC signal. The generated first bias DC signal is applied to the lower electrode. In one embodiment, the first DC signal may be applied to another electrode, such as the adsorption electrode 115 in the electrostatic chuck 114. In one embodiment, the second DC generator 32b is connected to the upper electrode and configured to generate a second DC signal. The generated second DC signal is applied to the upper electrode. In various embodiments, at least one of the first and second DC signals may be pulsed. The first and second DC generators 32a and 32b may be provided in addition to the RF power source 31, and the first DC generator 32a may be provided instead of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure inside the plasma processing space 10s is adjusted by the pressure adjusting valve. The vacuum pump may include a turbo molecular pump, a dry pump, or a combination thereof.

The controller 2 processes computer-executable instructions for instructing the plasma processing apparatus 1 to execute various steps described in the present disclosure. The controller 2 may be configured to control each of components of the plasma processing apparatus 1 to execute the various steps described herein. In an embodiment, part or all of the controller 2 may be included in the plasma processing apparatus 1. The controller 2 may include, for example, a computer 2a. The computer 2a may include, for example, a processor (central processing unit (CPU)) 2a1, a storage unit 2a2, and a communication interface 2a3. The processor 2a1 may be configured to perform various control operations based on a program stored in the storage unit 2a2. The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 through a communication line such as a local area network (LAN).

While various exemplary embodiments have been described above, various additions, omissions, substitutions and changes may be made without being limited to the exemplary embodiments described above. Indeed, the embodiments described herein may be embodied in a variety of other forms.

For example, the present embodiment describes, as an example, a case in which the plasma processing system includes the plasma processing apparatus 1 of the capacitively-coupled plasma (CCP) type, and the configuration of the plasma processing system is not limited thereto. For example, the plasma processing system may include a processing apparatus that includes a plasma generator of, for example, an inductively coupled plasma (ICP), an electron-cyclotron-resonance plasma (an ECR plasma), a helicon wave plasma (HWP), or a surface wave plasma (SWP). Further, a processing apparatus including various types of plasma generators including an alternating current (AC) plasma generator and a direct current (DC) plasma generator may be used.

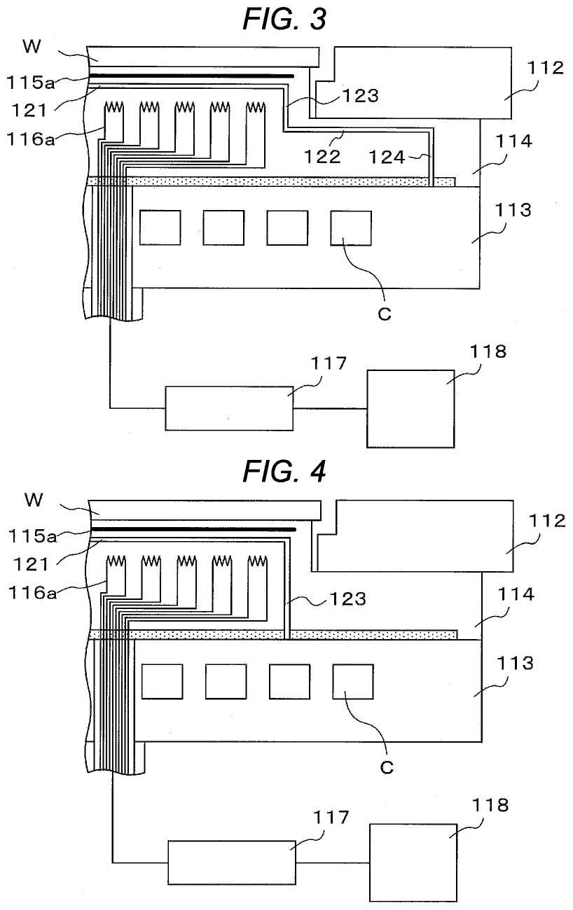

In addition, for example, as illustrated in FIG. 2, the present embodiment described, as an example, the case in which the heater electrode 116 includes the first heater electrodes 116a for heating the substrate W and the second heater electrodes 116b for heating the ring assembly 112. However, in the heater electrode 116 disposed in the electrostatic chuck 114, as illustrated in FIG. 3, the second heater electrodes 116b for heating the ring assembly 112 may be appropriately omitted.

In addition, in the case of omitting the second heater electrodes 116b in this way, as illustrated in FIG. 4, the second top plate member 122 and the second sidewall member 124 of the shield member 120 may be omitted, and the first top plate member 121 and the base 113 may be electrically connected to each other by the first sidewall member 123.

### Action and Effects of Substrate Support According to Present Disclosure

Accordingly, in the substrate support 11 according to the present embodiment, the shield member 120 made of a conductive metal material having a sufficiently low resistance value with respect to the radio-frequency power, is disposed in the electrostatic chuck 114.

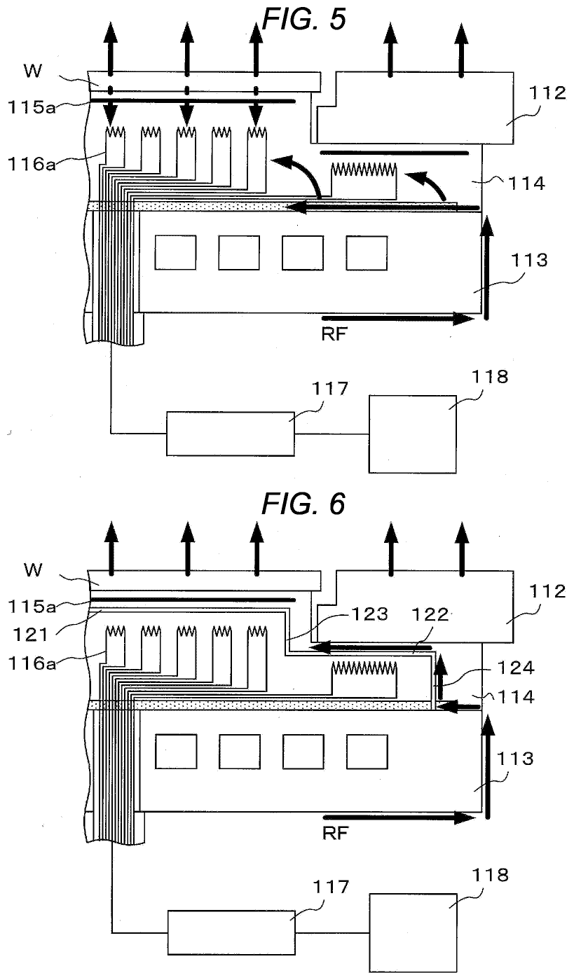

Here, the radio-frequency power applied to the conductive member of the base 113 during the plasma processing propagates through a surface of the base 113, which is a conductive member, and is supplied to the plasma processing space. In this case, in a substrate support 11′ in the prior art having no shield member 120 disposed, as illustrated in FIG. 5, a part of the radio-frequency power propagating through the surface of the base 113 may enter the heater electrode 116 disposed to be electrically floating in the electrostatic chuck 114. More specifically, due to a potential difference between the base 113 and the heater electrode 116, a part of the radio-frequency power propagating through the surface of the base 113 may enter the heater electrode 116 as a noise component, which further increases the potential difference and causes a discharge. Then, the noise component entering the heater electrode 116 or the generated discharge in this way may cause, for example, damage to the heater electrode 116 or the heating power source 118, and deterioration of the power efficiency.

In this respect, in the substrate support 11 according to the present embodiment, the shield member 120 disposed to obtain substantially the same potential as that of the base 113 is provided in the electrostatic chuck 114. Accordingly, even if the radio-frequency power is applied to the conductive member of the base 113, as illustrated in FIG. 6, the radio-frequency power propagates through the surface of the shield member 120 instead of the surface of the base 113. Therefore, the radio-frequency power is prevented from propagating through the surface of the base 113 to reach the vicinity of the heater electrode 116, thereby appropriately preventing the radio-frequency power from entering the heater electrode 116.

In the present embodiment, as described above, the heater electrode 116 to which the radio-frequency power may enter is accommodated in the equipotential space S defined by the base 113 and the shield member 120 that are disposed to obtain substantially the same potential. Accordingly, since the generation of the potential difference between the heater electrode 116 and the base 113 is prevented in the equipotential space S, the radio-frequency power is further appropriately prevented from entering the heater electrode 116.

According to the present embodiment, the radio-frequency power applied to the conductive member of the base 113 in this way can propagate through the surface of the shield member 120 to reach the vicinity of the surface of the electrostatic chuck 114, that is, the vicinity of the plasma processing space 10s, thereby improving the plasma generation efficiency during the plasma processing.

Further, according to the present embodiment, by disposing the first top plate member 121 and the second top plate member 122 at positions closer to the adsorption electrode 115 (the surface of the electrostatic chuck 114) than the heater electrode 116 as described above, the plasma generation efficiency may be further appropriately improved.

A case was described as an example in which the heater electrode 116 is disposed to be accommodated in the equipotential space S defined by the base 113 and the shield member 120 that are disposed to obtain substantially the same potential in the substrate support 11 according to the embodiment described above. However, the configuration of the substrate support 11 is not limited thereto, and may be any configuration as long as the entry of the radio-frequency power to the heater electrode 116 can be at least attenuated or prevented.

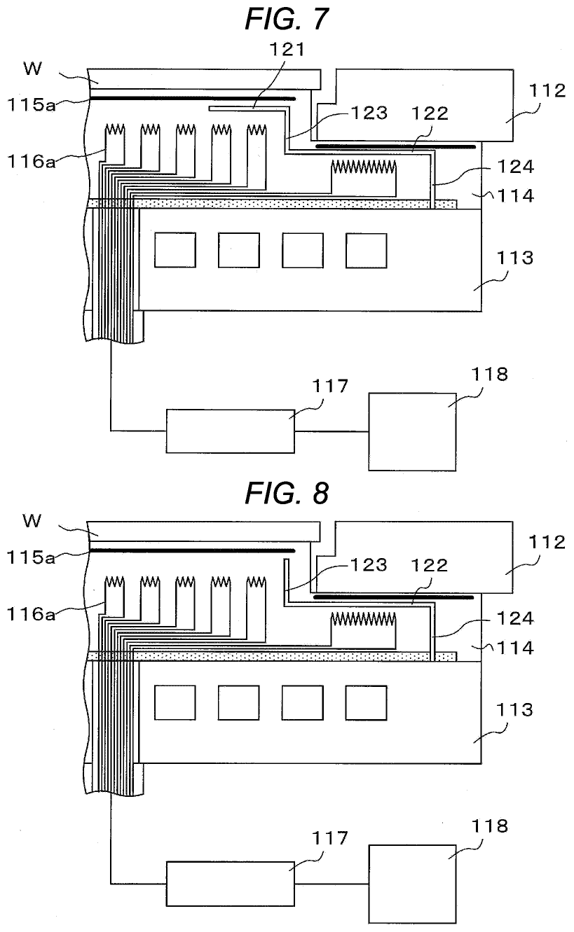

Specifically, for example, instead of configuring the first top plate member 121 in a disk shape to completely cover the first heater electrodes 116a in a plan view as illustrated in FIG. 2, the first top plate member 121 may be configured in a substantially annular shape to cover at least a part of the first heater electrodes 116a in a plan view as illustrated in FIG. 7. In other words, the heater electrode 116 may not necessarily be disposed to be accommodated in the equipotential space S. If the first top plate member 121 is configured in a substantially annular shape in this way, the radio-frequency power also propagates through surfaces of the second sidewall member 124, the second top plate member 122, and the first sidewall member 123 to reach the vicinity of the surface of the electrostatic chuck 114. Therefore, the entry of the radio-frequency power to the first heater electrode 116a can be at least attenuated. In addition, by configuring the first top plate member 121 in a substantially annular shape in this way, heat generation of the first heater electrodes 116a can be directly transferred to the substrate W without passing through the first top plate member 121. Therefore, the heating efficiency of the substrate W by the first heater electrodes 116a can be improved.

In addition, as long as the radio-frequency power can reach the vicinity of the surface of the electrostatic chuck 114 by the shield member 120 in this way, the first top plate member 121 may be omitted as illustrated in FIG. 8. In this case, it is also possible to at least attenuate the entry of the radio-frequency power to the first heater electrodes 116a, and to improve the heating efficiency of the substrate W by the first heater electrodes 116a.

Further, although not illustrated, as long as the radio-frequency power can reach the vicinity of the surface of the electrostatic chuck 114 in this way, both the first top plate member 121 and the second top plate member 122 of the shield member 120 may be omitted. In other words, the shield member 120 may be configured by only a sidewall member (the first sidewall member 123 or the second sidewall member 124).

Specifically, in a case in which the heater electrode 116 includes the first heater electrodes 116a and the second heater electrodes 116b as illustrated in FIG. 2, the shield member 120 may be configured by only the second sidewall member 124. In a case in which the heater electrode 116 includes only the first heater electrode 116a as illustrated in FIG. 3, the shield member 120 may be configured by only the first sidewall member 123.

In this case as well, by setting a position of an upper end portion of the shield member 120 (the first sidewall member 123 or the second sidewall member 124) at least above the heater electrode 116, more preferably, in the vicinity of the surface of the electrostatic chuck 114, the entry of the radio-frequency power to the first heater electrodes 116a can be at least attenuated.

As described above, the radio-frequency power applied to the conductive member of the base 113 propagates through the surfaces of the base 113 and the shield member 120 to reach the vicinity of the surface of the electrostatic chuck 114, that is, for example, the first top plate member 121. However, at this time, if at least a part of the first top plate member 121 is omitted as illustrated in FIGS. 7 and 8, a deviation occurs in the supply of the radio-frequency power to the plasma processing space 10s, and as a result, a deviation may occur in the uniformity of a plasma processing result with respect to the substrate W.

Therefore, from a viewpoint of improving the uniformity of the plasma processing result with respect to the substrate W, it is preferable to dispose the shield member 120 (specifically, the first top plate member 121 and the second top plate member 122) to uniformly cover the entire surface of the electrostatic chuck 114 in a plan view.

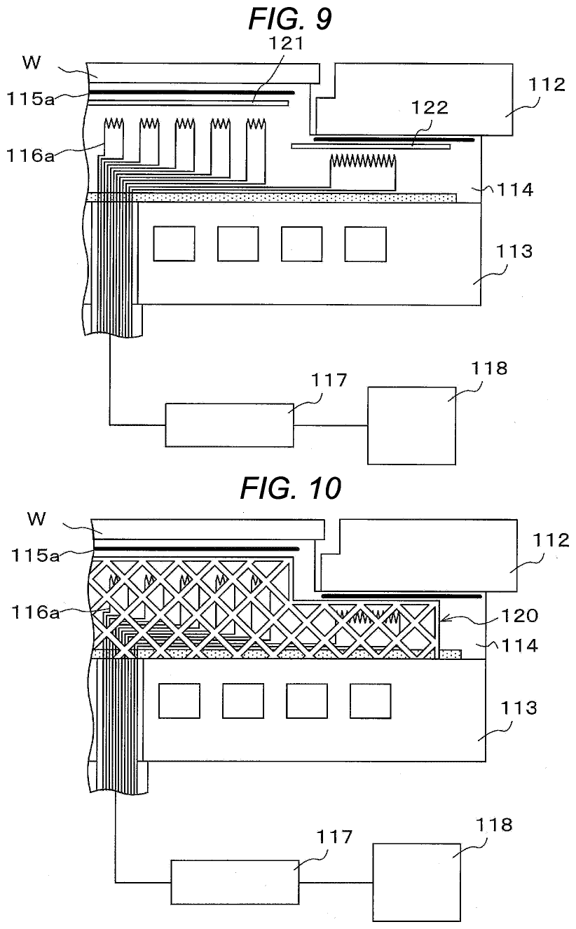

Here, in general, the electrostatic chuck 114 that holds the substrate W is configured to have a sufficiently larger size in a radial direction than a size in a thickness direction. Specifically, for example, the size of the electrostatic chuck 114 in the radial direction is about 300 mm or more in accordance with a size of the substrate W, whereas the size of the electrostatic chuck 114 in the thickness direction is about 10 mm or less. Therefore, when the shield member 120 is to be disposed in the electrostatic chuck 114 according to the present embodiment, the radio-frequency power propagating through the surface of the base 113 may be propagated to the surface of the top plate member (the first top plate member 121 or the second top plate member 122) by performing an impedance design by changing a providing position, a thickness, and the like of the shield member 120. In other words, by appropriately performing the impedance design, the entry of the radio-frequency power to the first heater electrode 116a can be attenuated even if the sidewall member (the first sidewall member 123 or the second sidewall member 124) of the shield member 120 is omitted as illustrated in FIG. 9. In other words, the shield member 120 is not necessarily to be disposed to obtain substantially the same potential as that of the base 113. By particularly disposing the first top plate member 121 as the shield member 120 in this way, the radio-frequency power can be propagated to the entire surface of the first top plate member 121 (the electrostatic chuck 114) in a plan view, and as a result, the uniformity of the plasma processing result with respect to the substrate W can be improved.

In the embodiment described above, in order to appropriately prevent the entry of the radio-frequency power to the heater electrode 116, the first top plate member 121 and the second top plate member 122 of the shield member 120 are formed of plate-shaped members having no holes respectively. Similarly, the first sidewall member 123 and the second sidewall member 124 are formed of plate-shaped members having no holes respectively, thereby bringing the base 113 and the shield member 120 into line contact with each other to surround the entire periphery of the heater electrode 116. However, as long as the entry of the radio-frequency power to the heater electrode 116 can at least be attenuated, the configuration of the shield member 120 is not limited thereto.

Specifically, for example, the sidewall member of the shield member 120 may be formed in a lattice shape (a mesh shape) as illustrated in FIG. 10. In other words, the top plate member and the sidewall member of the shield member 120 may have one or more holes. In such a case, it is also possible to propagate the radio-frequency power propagating through the surface of the base 113 along the surface of the shield member 120, that is, to attenuate the amount of the radio-frequency power propagating to the vicinity of the heater electrode 116, and as a result, it is possible to prevent the entry of the radio-frequency power to the heater electrode 116. In addition, if the first top plate member 121 is formed in a lattice shape in this manner, it is also possible to propagate the radio-frequency power to the entire surface of the first top plate member 121 (the electrostatic chuck 114) in a plan view, and as a result, it is possible to improve the uniformity of the plasma processing result with respect to the substrate W.

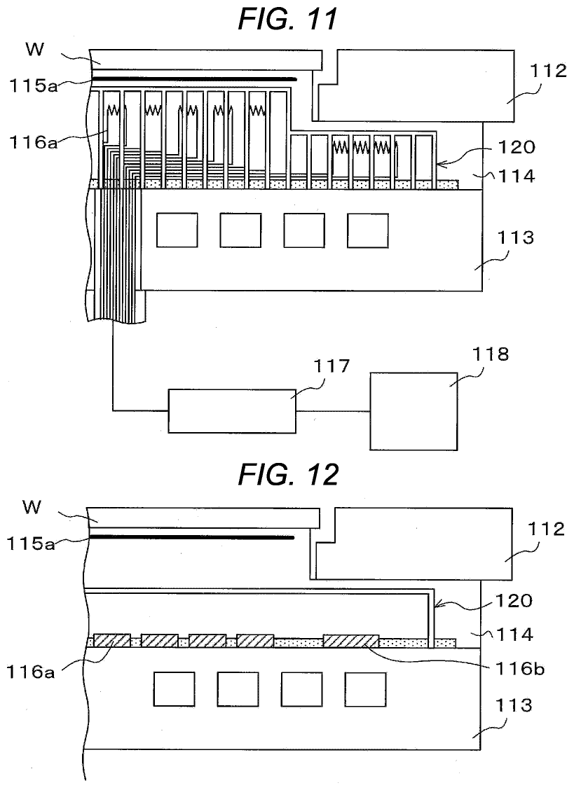

Similarly, it is also possible to attenuate at least the amount of radio-frequency power propagating to the vicinity of the heater electrode 116 by forming the sidewall member of the shield member 120 in a vertical lattice shape as illustrated in FIG. 11, and as a result, it is possible to prevent the entry of the radio-frequency power to the heater electrode 116.

In FIGS. 10 and 11, the case in which the sidewall member of the shield member 120 is configured in a lattice shape or a vertical lattice shape was described as an example, and naturally, the top plate member of the shield member 120 may be configured in a lattice shape or a vertical lattice shape. If the top plate member is configured in a lattice shape or a vertical lattice shape in this way, the radio-frequency power can also be propagated to the entire surface of the electrostatic chuck 114 in a plan view, and as a result, the uniformity of the plasma processing result with respect to the substrate W can be improved.

As illustrated in FIGS. 10 and 11, in a case in which the shield member 120 and the base 113 are brought into point contact with each other at points instead of being brought into line contact with each other over the entire periphery, if such contact point positions are not uniformly arranged around the heater electrode 116, a deviation may occur in the plasma processing result, or the shield member 120 and the base 113 may not be appropriately configured to obtain substantially the same potential.

Therefore, if the shield member 120 and the base 113 are brought into point contact with each other in this way, it is desirable that such contact point positions are evenly arranged over the entire periphery of the electrostatic chuck 114. Specifically, for example, if six contact points are designed, it is desirable to arrange the contact points every 60 degrees in a peripheral direction.

In addition, if the shield member 120 and the base 113 are brought into point contact with each other in this way, in order to appropriately configure the shield member 120 and the base 113 to obtain the same potential, it is desirable to increase the number of such contact points as much as possible.

The embodiment described above has described, as an example, a case in which the heater electrode 116 includes the first heater electrodes 116a and the second heater electrodes 116b, and the first heater electrodes 116a and the second heater electrodes 116b are integrally accommodated in the equipotential space S by one shield member 120. The first heater electrodes 116a and the second heater electrodes 116b may be accommodated independently each in an equipotential space S. In other words, the shield members 120 may be disposed in the electrostatic chuck 114 to form a plurality of equipotential spaces S, and the first heater electrodes 116a and the second heater electrodes 116b may be disposed in the respective equipotential spaces S.

The embodiment described above has described, as an example, a case in which the heater electrode 116 serving as an electric circuit is disposed in the electrostatic chuck 114, and the heater electrode 116 may be disposed to be at least in partial contact with the dielectric portion.

Specifically, in one embodiment, if the heater electrode 116 is to be disposed in the electrostatic chuck 114 or the adhesive member G serving as a dielectric portion, the heater electrode 116 may be disposed in the adhesive member G, or may be disposed to straddle between the electrostatic chuck 114 and the adhesive member G.

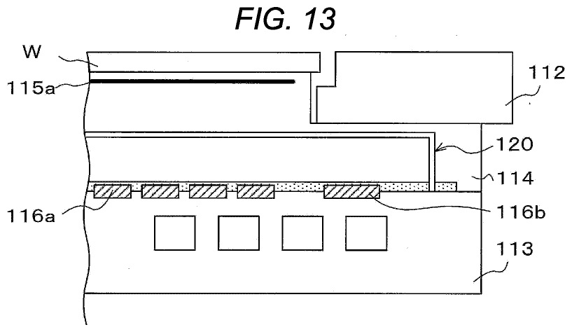

In addition, in one embodiment, if the heater electrode 116 is in contact with the electrostatic chuck 114 or the adhesive member G serving as a dielectric portion, the heater electrode 116 may have one surface in contact with the base 113 as illustrated in FIG. 12, or may be partially embedded in the base 113 as illustrated in FIG. 13.

In the substrate support 11 according to the present embodiment, as described above, the RF cut filter 117 for attenuating or preventing the radio-frequency power is provided on the power feeding cable that connects the heater electrode 116 and the heating power source 118. Accordingly, for example, even if the shield member 120 cannot completely prevent the radio-frequency power from entering the heater electrode 116, the noise component can be appropriately prevented from reaching the heating power source 118.

In particular, in the present embodiment, the amount of the radio-frequency power entering the heater electrode 116 is at least attenuated by an action of the shield member 120. Therefore, it is possible to more easily protect the heating power source 118 by the RF cut filter 117.

In other words, in the present embodiment, accordingly, the attenuation or prevention of the radio-frequency power entering the heater electrode 116 can be performed by the action of the shield member 120 alone. Therefore, in the substrate support 11 according to the present embodiment, the RF cut filter 117 disposed on the power feeding cable can be appropriately miniaturized or omitted.

In general, it is necessary to provide RF cut filters 117 in a lower space of the substrate support 11 (the electrostatic chuck 114) corresponding to temperature control regions defined by each of the heater electrodes 116 or combinations thereof. That is, it is necessary to dispose the RF cut filters 117 and the power feeding cables for connecting the RF cut filters 117 in the lower space of the substrate support 11, which may occupy the lower space of the substrate support 11.

In this respect, according to the present embodiment, by providing the shield member 120 in the electrostatic chuck 114, the RF cut filter 117 can be miniaturized or omitted as described above. Therefore, the power feeding cable and the RF cut filter 117 disposed in the lower space of the substrate support 11 (the electrostatic chuck 114) can be reduced, the spatial efficiency of the lower space can be improved, and the cost of providing the substrate support 11 can be reduced.

In the substrate support 11 in the prior art, the radio-frequency power entering the heater electrode 116 as a noise component may be consumed when passing through the RF cut filter 117, that is, the RF cut filter 117 may act as a resistor, thereby lowering the power efficiency. In addition, if there is particularly a deviation in the resistance value of the RF cut filter 117 at this time, such variation in resistance value may appear as an apparatus difference of the plasma processing apparatus 1.

In this respect, according to the present embodiment, since the provision of the RF cut filter 117 can be omitted in this way, the power loss due to the RF cut filter 117 can be prevented to improve the power efficiency, and the apparatus difference problem caused by the RF cut filter 117 can be solved.

The embodiment described above has described, as an example, a case in which the shield member 120 for limiting or preventing the entry of the radio-frequency power to the electric circuit is disposed in the electrostatic chuck 114, or more broadly, in the substrate support 11 configuring a lower electrode mechanism. However, the shield member according to the technique of the present disclosure is not limited to being provided at this position, and can be disposed on any member having therein an electric circuit to be prevented from the entry of radio-frequency power.

Specifically, for example, in a case where an upper electrode mechanism instead of the lower electrode mechanism in the plasma processing apparatus 1 includes an electric circuit therein, the shield member may be disposed in the upper electrode mechanism.

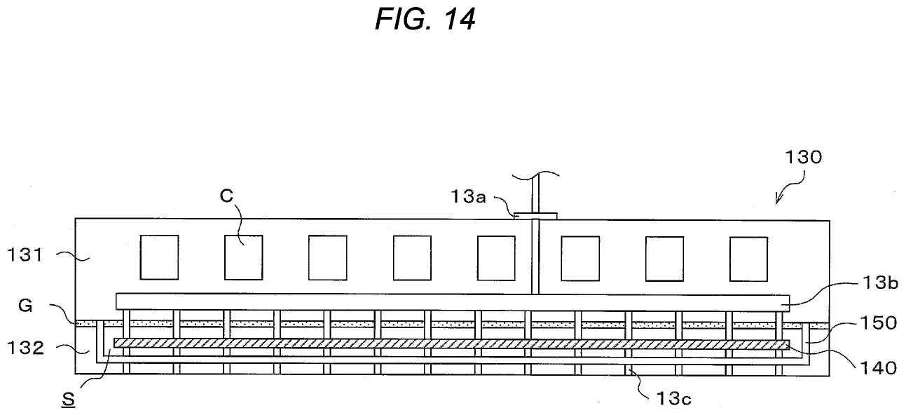

FIG. 14 is a cross-sectional view illustrating a schematic configuration of an upper electrode mechanism 130 according to one embodiment. As illustrated in FIG. 14, in one embodiment, the upper electrode mechanism 130 includes a metal plate 131 serving as an electrode portion and a shower head 132. The metal plate 131 and the shower head 132 are laminated via the adhesive member G. In the present embodiment, the shower head 132 and the adhesive member G configuring the upper electrode mechanism 130 correspond to the “dielectric portion” according to the technique of the present disclosure.

The metal plate 131 is configured by, for example, a conductive member such as an Al alloy. The conductive member of the metal plate 131 functions as the upper electrode. The gas supply port 13a and the gas diffusion chamber 13b are formed in the metal plate 131. The metal plate 131 has at least one flow path C therein for controlling the temperature of the shower head 132 whose temperature fluctuates due to a heat input of plasma. A heat transfer medium (fluid for temperature control) from a chiller unit (not illustrated) is circulated and supplied to the flow path C.

The gas introduction ports 13c are formed through the shower head 132 in a thickness direction (a vertical direction). Each of the gas introduction ports 13c is connected to the gas supply 20 via the gas diffusion chamber 13b and the gas supply port 13a formed in the metal plate 131, and is configured to introduce at least one processing gas from the gas supply 20 to the plasma processing space 10s. The shower head 132 has at least one heater electrode 140 therein for controlling the temperature of the shower head 132 whose temperature fluctuates due to the heat input of plasma. In the present embodiment, the heater electrode 140 corresponds to the “electric circuit” according to the technique of the present disclosure.

In one embodiment, a shield member 150 for attenuating or preventing the entry to the heater electrode 140 of the radio-frequency power applied to the conductive member (the upper electrode) of the metal plate 131 is disposed in the upper electrode mechanism 130, more specifically, in the shower head 132. The shield member 150 is made of, for example, a conductive metal material having a sufficiently low resistance value with respect to the radio-frequency power to be applied to the upper electrode (for example, tungsten or titanium). In addition, in one embodiment, the shield member 150 is disposed in the shower head 132 to obtain the same potential as that of the metal plate 131 to surround at least the periphery of the heater electrode 140. In other words, in one embodiment, the upper electrode mechanism 130 accommodates the heater electrode 140, in which the entry of the radio-frequency power is expected, in the equipotential space S defined by the metal plate 131 and the shield member 120 that are disposed to obtain substantially the same potential.

In the upper electrode mechanism 130 according to one embodiment, the shield member 150 is disposed in the shower head 132 in this way, so that the radio-frequency power applied to the upper electrode propagates through the surfaces of the metal plate 131 and the shield member 150 and reaches the vicinity of the surface of the shower head 132, that is, the vicinity of the plasma processing space 10s. As a result, it is possible to appropriately prevent the radio-frequency power from entering the heater electrode 140.

The configuration of the shield member 150 disposed in the shower head 132 is not limited to the illustrated example. That is, similar to the shield member 120 disposed in the electrostatic chuck 114, either the top plate member or the sidewall member configuring the shield member 150 may be omitted, or the top plate member and the sidewall member may be configured in a lattice shape or a vertical lattice shape.

The heater electrode 140 serving as the electric circuit is not limited to being disposed as in the illustrated example, and may be disposed being in partial contact with the dielectric portion.

Specifically, in one embodiment, if the heater electrode 140 is to be disposed in the shower head 132 or the adhesive member G serving as a dielectric portion, the heater electrode 140 may be disposed in the adhesive member G, or may be disposed to straddle between the shower head 132 and the adhesive member G.

In addition, in one embodiment, if the heater electrode 140 is in contact with the shower head 132 or the adhesive member G serving as a dielectric portion, the heater electrode 140 may have one surface in contact with the metal plate 131, or may be partially embedded in the metal plate 131.

Accordingly, the shield member according to the technique of the present disclosure may be disposed in any member having therein an electric circuit to be prevented from the entry of radio-frequency power, without being not limited to the electrostatic chuck 114 of the lower electrode mechanism.

The embodiment described above has described a case as an example in which the protection target electric circuit to be prevented from the entry of radio-frequency power is a heater electrode, and the type of the electric circuit is not limited thereto. For example, the shield member may be disposed to protect any electric circuit that may cause a problem due to the entry of radio-frequency power, such as a thermocouple, a piezoelectric element, or a driving mechanism of another part.

It shall be understood that the embodiments disclosed herein are illustrative and are not restrictive in all aspects. The embodiment described above may be omitted, replaced, or modified in various forms without departing from the scope and spirit of the appended claims.

1. A plasma processing apparatus, comprising:
a processing chamber; and
an electrode mechanism used for plasma processing,
wherein the electrode mechanism includes:
an electrode portion configured to be applied with radio-frequency power;
a dielectric portion disposed to laminate with the electrode portion;
an electric circuit at least partially disposed in the dielectric portion; and
a shield member disposed in the dielectric portion to overlap at least a part of the electric circuit in at least one of a plan view or a side view.

2. The plasma processing apparatus according to claim 1, wherein the shield member is disposed to have the same potential as that of the electrode portion.

3. The plasma processing apparatus according to claim 2, wherein the shield member attenuates at least passage of the radio-frequency power applied to the electrode portion.

4. The plasma processing apparatus according to claim 1, wherein the shield member is made of any material selected from tungsten or titanium.

5. The plasma processing apparatus according to claim 1, wherein the electrode mechanism is a lower electrode mechanism used for plasma processing and includes a substrate support configured to support a substrate on a substrate support surface,
the electric circuit includes a first heater electrode configured to heat the substrate supported on the substrate support surface, and
the shield member is disposed to accommodate the first heater electrode integrally with the electrode portion.

6. The plasma processing apparatus according to claim 5, wherein the shield member includes:
a top plate member disposed along a surface direction of the dielectric portion; and
a sidewall member disposed along a thickness direction of the dielectric portion and electrically connecting the top plate member and the electrode portion.

7. The plasma processing apparatus according to claim 6, wherein the top plate member is disposed between the substrate support surface and the first heater electrode in the dielectric portion, and
a distance between the first heater electrode and the top plate member is at least larger than a distance between the substrate support surface and the top plate member.

8. The plasma processing apparatus according to claim 6, wherein the sidewall member is disposed in line contact with the electrode portion to surround an entire periphery of the first heater electrode.

9. The plasma processing apparatus according to claim 6, wherein the sidewall member is disposed in point contact with the electrode portion at contact points in a peripheral direction of the electrode portion to surround an entire periphery of the first heater electrode.

10. The plasma processing apparatus according to claim 9, wherein the contact points between the electrode portion and the sidewall member are arranged at equal intervals in the peripheral direction of the electrode portion.

11. The plasma processing apparatus according to claim 5, wherein the substrate support includes a ring support surface configured to support an edge ring,
the electric circuit includes a second heater electrode configured to heat the edge ring supported by the ring support surface, and
the shield member is disposed to integrally accommodate the first heater electrode and the second heater electrode.

12. The plasma processing apparatus according to claim 5, wherein the substrate support includes a ring support surface configured to support an edge ring,
the electric circuit includes a second heater electrode configured to heat the edge ring supported by the ring support surface, and
the shield member is disposed to independently accommodate the first heater electrode and the second heater electrode.

13. The plasma processing apparatus according to claim 1, wherein the electrode mechanism is an upper electrode mechanism used for plasma processing, and includes a shower head configured to supply a processing gas into a processing space where a substrate is accommodated during the plasma processing,
the electric circuit is a heater electrode configured to heat the shower head, and
the shield member is disposed to accommodate the heater electrode integrally with the electrode portion.

14. An electrode mechanism used for plasma processing, the electrode mechanism comprising:
an electrode portion configured to be applied with radio-frequency power during plasma processing;
a dielectric portion disposed to laminate with the electrode portion;
a heater electrode at least partially disposed in the dielectric portion and configured to heat the dielectric portion; and
a shield member disposed in the dielectric portion to accommodate the heater electrode integrally with the electrode portion,
wherein the electrode mechanism propagates the radio-frequency power applied to the electrode portion to an outer surface of the shield member.
